(19) United States
(12) Patent Application Publication
(10) Pub. No.: US 2004/0164364 A1
(43) Pub. Date: Aug. 26, 2004

(54) Semiconductor device and its manufacturing method

(76) Inventor: Shigeru Fujita, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/785,005

(22) Filed: Feb. 25, 2004

Related U.S. Application Data
(62) Division of application No. 10/390,768, filed on Mar. 19, 2003.

(30) Foreign Application Priority Data
Mar. 22, 2002 (JP) P2002-080316

(51) Int. Cl. H01L 29/76

(52) U.S. Cl. 257/410

(57) ABSTRACT

A semiconductor device including a p-channel MIS transistor and using a high-dielectric-constant film as its gate insulating film is configured to prevent a p-type impurity from undesirably diffusing from a p-type silicon layer used as the gate electrode through a gate insulating film into the underlying semiconductor substrate, thereby to prevent fluctuation of the threshold voltage of the p-channel MIS transistor. For this purpose, the p-channel MIS transistor is fabricated by forming a nitride film by nitriding of the top surface of the high-dielectric-constant film formed on a silicon substrate, then forming the gate electrode including boron-doped p-type polycrystalline silicon layer on the nitride layer such that the enhanced dielectric layer and the on nitride layer function as the gate insulating film as a whole, and thereafter forming a source region and a drain region both of a p⁺-type in a self aligned manner with the gate electrode.

### BACKGROUND OF THE INVENTION

1. Field of the Invention

This invention relates to a semiconductor device and its manufacturing method suitable for application to a semiconductor device that includes a MIS (metal-insulator-semiconductor) transistor using a p-type impurity-contained silicon layer as its gate electrode, for example.

2. Description of the Related Art

For manufacturing a MOS (metal-oxide-semiconductor) type semiconductor device using a silicon substrate, for example, a gate insulating film made of a silicon oxide film must be formed on the top surface of the silicon substrate. It is no exaggeration to say that the silicon oxide film as the gate insulating film determines the reliability of the MOS type semiconductor device. Therefore, the silicon oxide film is always required to maintain high resistance to dielectric breakdown voltage and long-term reliability.

In recent MOS type semiconductor devices, gate insulating films are getting thinner and thinner as well along with enhancement of the degree of integration. In MOS type semiconductor devices belonging to the generation of the 0.07 μm gate length, thickness of silicon oxide films as gate insulating films are expected to go down to the order of 1.2 nm. However, since a single layer of such a thin silicon oxide film allows the gate leak current to increase, the silicon oxide film is going to encounter the limit of reduction in thickness. Under the circumstances, researches are in progress toward employment of high-dielectric-constant films having sufficiently higher dielectric coefficients than silicon oxide films as new gate insulating films replacing silicon oxide films.

On the other hand, in recent CMOS transistors, efforts are being made to lower the operation voltage for the purpose of reducing the power consumption. Accordingly, sufficiently low and symmetric threshold voltages are required for both p-channel MOS transistors and n-channel MOS transistors constituting CMOS transistors. To cope with the requirement, gate electrodes using p-type polycrystalline silicon layers containing p-type impurities are used in p-channel MOS transistors instead of gate electrodes using n-type polycrystalline silicon layers containing n-type impurities, which have been used heretofore. However, due to various kinds of annealing carried out in the manufacturing process of the semiconductor device after the step of forming the gate electrode, boron (B) atoms typically used as a p-type impurity diffuse from the gate electrode, readily reach the silicon substrate through the gate insulating film, and change the threshold voltage of the p-channel MOS transistor. This phenomenon appears more remarkably when the gate insulating film is thinned more for lowering the operation voltage.

Fluctuation of the threshold voltage of a p-channel MOS transistor caused by diffusion of boron atoms into the silicon substrate similarly occurs also when a high-dielectric-constant film is used as the gate insulating film in lieu of the thin silicon oxide film because the high-dielectric-constant film allows boron atoms to easily pass through by diffusion. Therefore, it remains as a very serious problem.

### OBJECTS AND SUMMARY OF THE INVENTION

It is therefore an object of the invention to provide a semiconductor device capable of effectively preventing a p-type impurity in a p-type silicon layer used as a gate electrode from diffusing into an underlying semiconductor substrate through a gate insulating film and thereby causing fluctuation of the threshold voltage of a transistor when a high-dielectric-constant film is used as the gate insulating film, and to provide a manufacturing method of the semiconductor device.

In a more general view, it is an object of the invention to provide a semiconductor device capable of effectively preventing a p-type impurity from diffusing from a p-type impurity-contained layer above a high-dielectric-constant film into an underlying semiconductor substrate through the high-dielectric-constant film and behaving undesirably, and to provide a manufacturing method of the semiconductor device.

According to the first aspect of the invention, there is provided a semiconductor device comprising:

a semiconductor substrate;

a high-dielectric-constant film on the semiconductor substrate; and

a nitride layer on the high-dielectric-constant film.

According to the second aspect of the invention, there is provided a method of manufacturing a semiconductor device comprising the steps of:

forming a high-dielectric-constant film on a semiconductor substrate; and

forming a nitride layer over the top surface of the high-dielectric-constant film.

According to the third aspect of the invention, there is provided a semiconductor device comprising:

A semiconductor substrate;

a gate insulating film on the semiconductor substrate; and

a gate electrode formed on the gate insulating film and including at least a p-type impurity-contained layer,

wherein the gate insulating film includes a high-dielectric-constant film and a nitride layer on the high-dielectric-constant film.

According to the fourth aspect of the invention, there is provided a method of manufacturing a semiconductor device comprising the steps of:

forming a gate insulating film on a semiconductor substrate; and

forming a gate electrode including at least a p-type impurity-contained layer on the gate insulating film,

wherein the step of forming the gate insulating film includes a step of forming a high-dielectric-constant film on the semiconductor substrate, and a step of forming a nitride layer on the top surface of the high-dielectric-constant film.

Basically, the high-dielectric-constant film used in the present invention may be made of a material selected from a variety of enhanced dielectric materials. Its examples are films of Al₂O₃, ZrO₂, HfO₂, PrO₂, and so on, their silicate films, films of multi-element materials of those elements (for example, HfAlOₓ as a ternary material), and multi-layered structures of two or more layers of those films (for example, Al₂O₃/HfO₂/Al₂O₃ multi-layered structure).

Various methods and techniques are usable for forming the high-dielectric-constant film, such as ALD (atomic layer deposition), metal organic chemical vapor deposition (MOCVD), sputtering, and so on.

The semiconductor substrate as the base layer of the enhanced dielectric material may be a bulk semiconductor substrate, a semiconductor layer formed on any substrate, with or without devices formed thereon. More specifically, the semiconductor substrate may be selected from single-crystal silicon substrates (single-crystal silicon wafers), single-crystal silicon layers epitaxially grown on silicon substrates or other semiconductor substrates, polycrystalline silicon layers or amorphous silicon layers formed on semiconductor substrates or other semiconductor substrates, and semiconductor layers made of silicon and germanium (Si—Ge layers). If a single-crystal silicon substrate is employed, it may be obtained by cutting single-crystal silicon made by a crystal growth technique such as CZ (Czochralski) method, MCZ (magnetic field applied Czochralski) method, DLCZ (double-layered Czochralski) method, FZ (floating zone) method, or the like, which may be combined with hydrogen annealing for inactivating dangling bonds.

The nitride layer is typically formed by direct nitriding of the top surface of the high-dielectric-constant film, but may be formed by depositing a nitride layer on the high-dielectric-constant film. In the former case, composition of the nitride layer corresponds to the composition of the high-dielectric-constant film, and generally includes nitrogen in addition to the composition of the high-dielectric-constant film. For example, if the high-dielectric-constant film is an Al₂O₃ film, then the nitride layer will be a composition of Al, O and N. In the latter case, composition of the nitride layer may be determined independently from the composition of the high-dielectric-constant film. For example, if the high-dielectric-constant film is an Al₂O₃ film, a compound layer of Al, O and N may be formed as the nitride layer.

In case the top surface of the high-dielectric-constant film undergoes direct nitriding, plasma nitriding or remote plasma nitriding is preferably used. In this case, more preferably, radical nitrogen generated in plasma is used. In some cases, however, thermal nitriding may be used, for example. Thickness of the nitride layer is determined to be thick enough to prevent diffusion of a p-type impurity such as boron. However, if the dielectric constant of the nitride layer is lower than the dielectric constant of the high-dielectric-constant film, the total dielectric constant of the high-dielectric-constant film and the nitride layer decreases from the own dielectric constant of the enhanced dielectric layer, and this tendency progresses as the nitride layer becomes thicker. Therefore, to prevent it and make the best use of the high dielectric constant of the high-dielectric-constant film, the nitride layer had better be as thin as possible. For example, thickness of the nitride layer is determined not to exceed 0.5 nm, although it depends on the material and thickness of the high-dielectric-constant film.

Basically, the p-type impurity-contained layer may be made of any material selected from a variety of enhanced dielectric materials. Typically, however, it is a silicon layer (single-crystal, polycrystalline or amorphous silicon layer) containing boron. For example, the gate electrode may be a simplex p-type polycrystalline silicon layer containing boron, or may be a polycide layer made by stacking a metal silicide layer with a high melting point (such as a tungsten silicide layer) on a p-type polycrystalline silicon layer containing boron.

The semiconductor device is typically a semiconductor device using a MIS transistor, or especially a p-channel MIS transistor. More specifically, it may be a MIS semiconductor device, complementary MIS semiconductor device, bipolar complementary MIS semiconductor device, or the like, and it is usable in Dynamic RAM and any other purposes.

According to the invention summarized above, since the nitride layer can prevent diffusion of p-type impurities such as boron with its close-packed structure, by forming the nitride layer on the enhanced dielectric layer, it is possible to prevent a p-type impurity from passing through the high-dielectric-constant film from a p-type impurity-contained layer formed above the high-dielectric-constant film, such as a p-type impurity-contained polycrystalline silicon layer forming a part or the entirety of the gate electrode, for example.

The above and other objects and features of the present invention will become apparent from the following detailed description and the appended claims with reference to the accompanying drawings.

### BRIEF DESCRIPTION OF THE DRAWINGS

FIG. 1 is a cross-sectional view for explaining a manufacturing method of a complementary MIS semiconductor device according to an embodiment of the invention;

FIG. 2 is a cross-sectional view for explaining the manufacturing method of the complementary MIS semiconductor device according to the same embodiment of the invention;

FIG. 3 is a cross-sectional view for explaining the manufacturing method of the complementary MIS semiconductor device according to the same embodiment of the invention;

FIG. 4 is a cross-sectional view for explaining the manufacturing method of the complementary MIS semiconductor device according to the same embodiment of the invention;

FIG. 5 is a cross-sectional view for explaining the manufacturing method of the complementary MIS semiconductor device according to the same embodiment of the invention;

FIG. 6 is a cross-sectional view for explaining the manufacturing method of the complementary MIS semiconductor device according to the same embodiment of the invention;

FIG. 7 is a cross-sectional view for explaining the manufacturing method of the complementary MIS semiconductor device according to the same embodiment of the invention;

FIG. 8 is a cross-sectional view for explaining the manufacturing method of the complementary MIS semiconductor device according to the same embodiment of the invention;

FIG. 9 is a cross-sectional view for explaining the manufacturing method of the complementary MIS semiconductor device according to the same embodiment of the invention; and

FIG. 10 is a schematic diagram exemplifying a radical nitriding apparatus used for surface nitriding of an enhanced dielectric layer in a manufacturing method of a complementary MIS semiconductor device according to an embodiment of the invention.

### DETAILED DESCRIPTION OF THE PREFERRED EMBODIMENTS

Preferred embodiments of the invention will now be explained below with reference to the drawings. In all figures showing embodiments, common elements are labeled with common reference numerals.

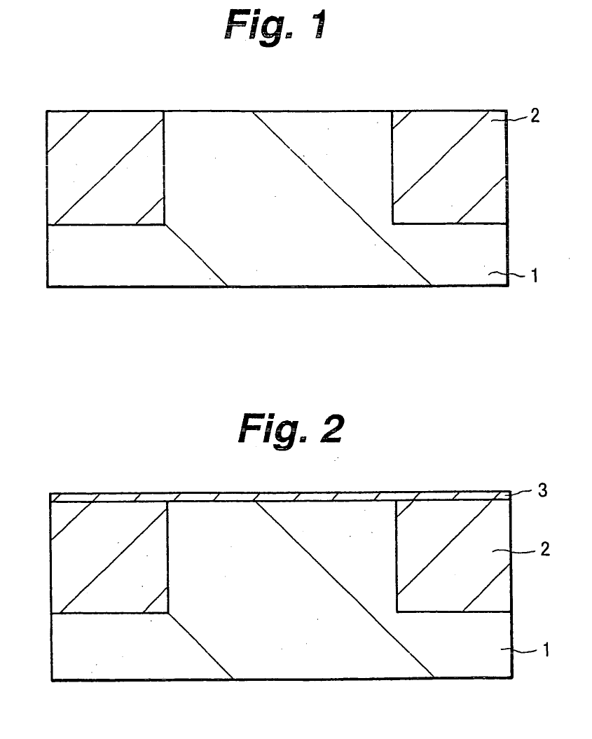

FIGS. 1 through 9 show a manufacturing method of a complementary MIS semiconductor device according to an embodiment of the invention. In the complementary MIS semiconductor device shown here, both an n-channel MIS transistor and a p-channel MIS transistor are used. However, only a portion for forming a p-channel MIS transistor is illustrated in FIGS. 1 through 9 and explained in the following description.

In this embodiment, first as shown in FIG. 1, a device isolating region 2, which may be a SiO₂ film, is selectively formed on a single-crystal silicon substrate 1 by an existing method. Thereafter, n wells (not shown) are formed in the silicon substrate 1 by selectively introducing ions of an n-type impurity such as phosphorus (P). After that, an n⁺-type channel stop region is formed (not shown) in the n-wells directly under the device isolating region 2 by selectively introducing ions of an n-type impurity. Thereafter, ions are introduced into an active region of the silicon substrate 1 for the purpose of adjusting the threshold voltage of the p-channel MIS transistor (channel doping). In the next step, minute particles and metal impurities are removed from the top surface of the silicon substrate 1 by RCA cleaning, for example. Additionally, the top surface of the silicon substrate 1 is cleaned with 0.1% hydrofluoric acid solution and pure water, for example.

Next as shown in FIG. 2, the high-dielectric-constant film 3 is formed on the silicon substrate 1 by ALD, for example. The high-dielectric-constant film 3 may be any of the examples already shown above. More specifically, here is used an Al₂O₃ film having the physical thickness of 2.5 nm and the SiO₂ film-reduced thickness of 1.7-1.8 nm, or a HfO₂ film having the physical thickness of 4.0 nm and the SiO₂ film-reduced thickness of 1.5 nm is used as the high-dielectric-constant film 3.

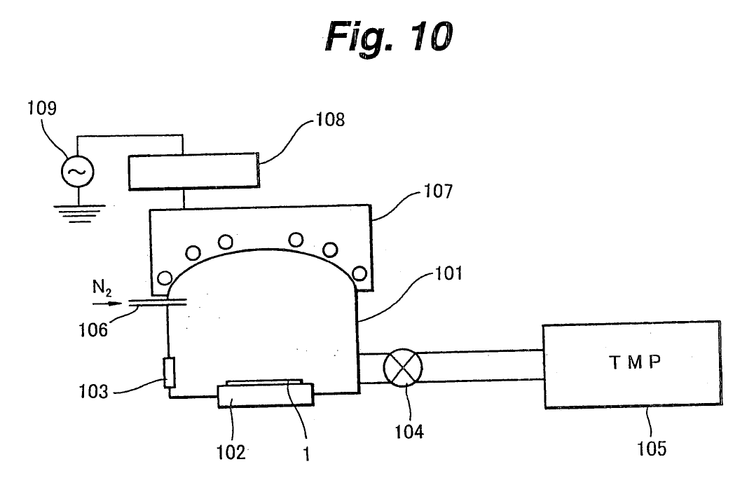

After that, for the purpose of conducting nitriding of the top surface of the high-dielectric-constant film 3, the silicon substrate 1 is introduced into a sheet-fed radical nitriding apparatus as shown in FIG. 10. Configuration of the radical nitriding apparatus is explained below.

As shown in FIG. 10, the radical nitriding apparatus includes a susceptor 102 located in a lower level in its processing chamber 101 such that a silicon substrate 1 can be supported on the susceptor 102. The susceptor 102 can be heated by a heater, not shown. The silicon substrate 1 is introduced into the processing chamber 101 and discharged therefrom through a substrate inlet 103 made in a lower sidewall portion of the processing chamber 101. In another lower sidewall portion different from that of the substrate inlet 103, a turbo molecular pump (TMP) 105 is connected via a throttle valve 104 to enable oil-free vacuum evacuation of the processing chamber 101 by the turbo molecular pump 105. The processing chamber 101 further has a gas inlet 106 in an upper sidewall portion to introduce nitrogen (N₂) gas into the processing chamber 101 through the gas inlet 106. Above the processing chamber 101, a high-frequency (RF) generator 107 is provided. The high-frequency generator 107 is connected to a RF power source 109 via a RF matching box 108.

For carrying out nitriding processing in the radical nitriding apparatus shown in FIG. 10, a silicon substrate 1 is introduced into the processing chamber 101 through the substrate inlet 103 and put on the susceptor 102. Then, while the processing chamber 101 is evacuated by the turbo molecular pump 105, N₂ gas is introduced into the processing chamber 101 through the gas inlet 106, RF is generated simultaneously by the high-frequency generator 107. By application of the RF power, radical nitrogen is produced from N₂ gas in the upper area inside the processing chamber 101, and the nitriding process of the top surface portion of the high-dielectric-constant film 3 is performed by the radical nitrogen. In this process, it is important to limit the nitriding processing only to the very top surface portion of the high-dielectric-constant film 3 and not to extend it deeper in the high-dielectric-constant film 3 or to the underlying silicon substrate 1. Nitriding using radical nitrogen is an excellent technique in this respect. Conditions for the nitriding may be as follows.

| | |
|---|---|
| Source RF power | 12.56 MHz, 200˜1000 W |
| Pressure | 10˜100 mTorr |
| Time | around 20˜60 seconds |
| Gas | N₂, 300˜400 sccm |

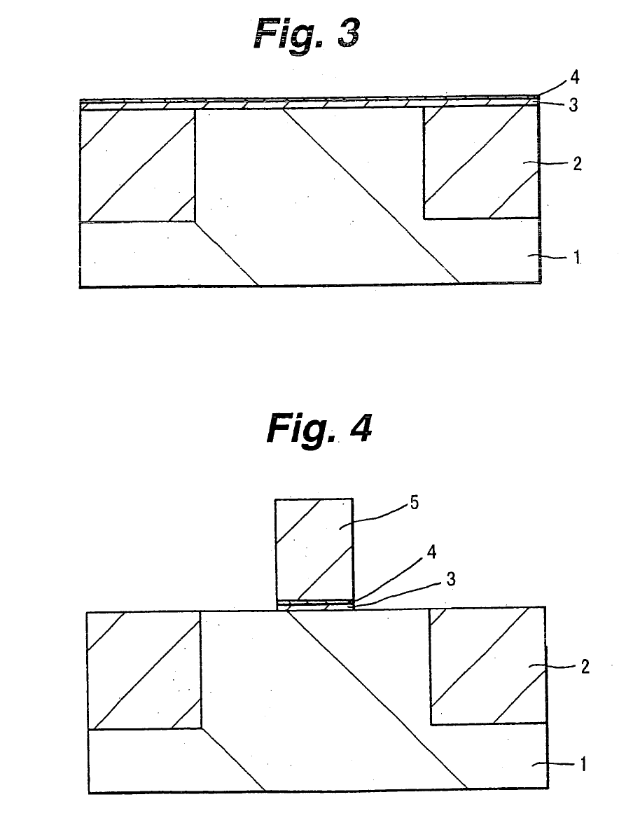

In this manner, a very thin top surface portion of the high-dielectric-constant film 3 is changed to the nitride film 4 as shown in FIG. 3. Thickness of the nitride layer 4 is 0.2-0.3 nm, for example.

After that, a non-doped polycrystalline silicon film is formed on the entire substrate surface by low-pressure CVD, for example, and B as a p-type impurity is doped into the polycrystalline silicon film by ion implantation, for example. Thereafter, a resist pattern (not shown) of a predetermined geometry is formed on the B-doped p-type polycrystalline silicon film by lithography. Next using this resist pattern as a mask, the p-type polycrystalline silicon film is patterned together with the underlying nitride layer 4 and high-dielectric-constant film 3 by anisotropic dry etching such as reactive ion etching (RIE). As a result, the gate electrode 5 is made out as shown in FIG. 4. The resist pattern is removed thereafter. In this case, the entirety of the high-dielectric-constant film 3 and the nitride layer 4 between the gate electrode 5 and the silicon substrate 1 constitutes the gate insulating film.

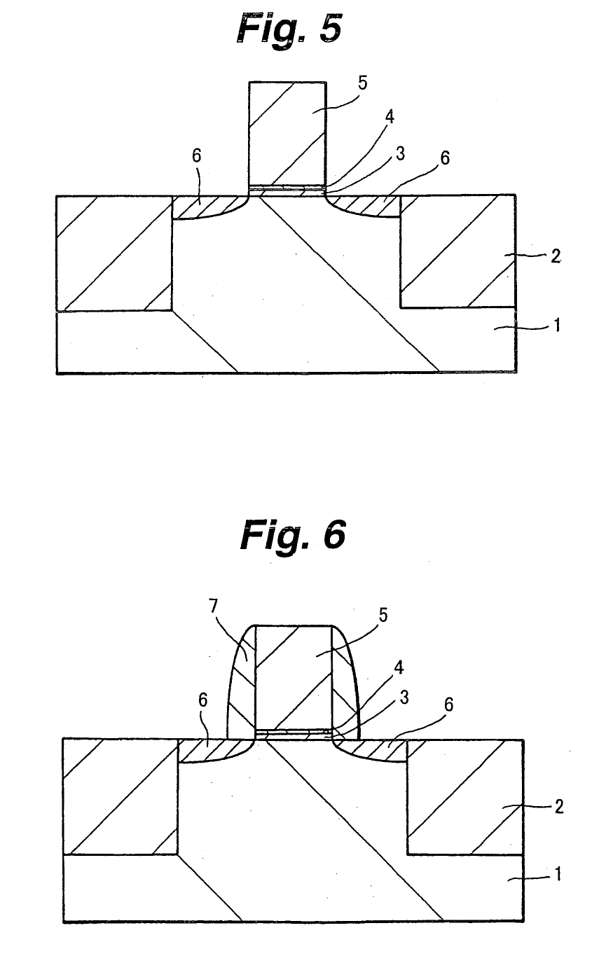

Subsequently, as shown in FIG. 5, using the gate electrode 5 as a mask, a quantity of a p-type impurity enough to make a low concentration is introduced into the silicon substrate 1 by ion implantation to form a p⁻-type low impurity-concentrated region 6 in self alignment with the gate electrode 5. The region 6 forms low impurity-concentrated portions of source and drain regions to be formed later. The p-type impurity used here may be B or BF₂, for example.

Next as shown in FIG. 6, an insulating film such as silicon oxide film or silicon nitride film is formed on the entire substrate surface by normal-pressure CVD or low-pressure CVD, for example, and thereafter etched vertically to the substrate surface by anisotropic dry etching such as RIE to make out a sidewall spacer 7 of that insulator on the sidewall of the gate electrode 5.

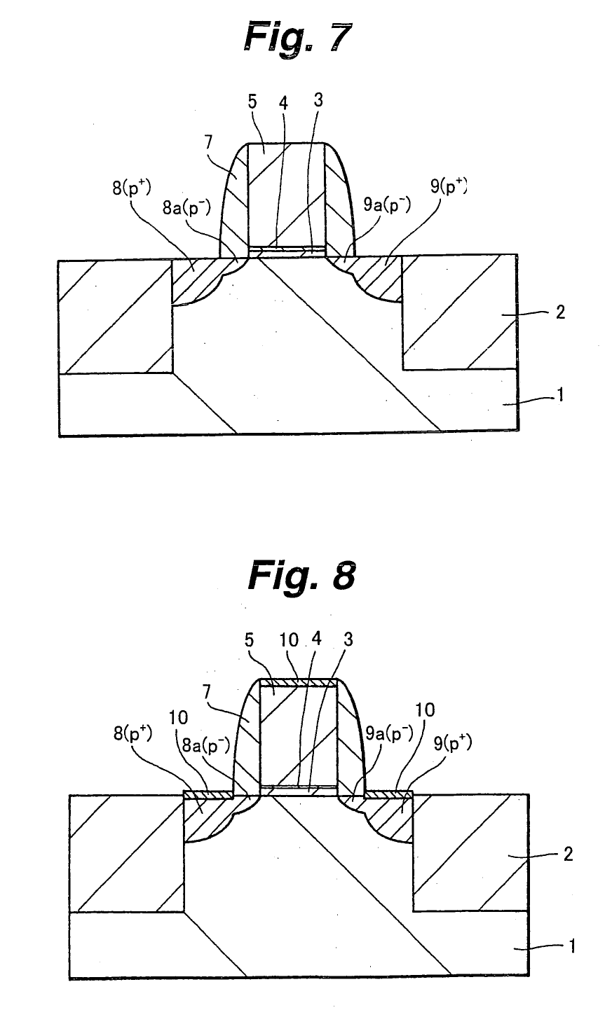

In the next process, as shown in FIG. 7, using the gate electrode 5 and the sidewall spacer 7 as a mask, a source region 8 and a drain region 9, both of a p⁺-type, for example, are formed in self alignment with the gate electrode 5 by ion implantation of a p-type impurity into n wells to a high concentration. The p-type impurity used here may be B or BF₂, for example. The low impurity-concentrated region 6 formed in the preceding process constitutes p-type low impurity-concentrated portions 8a, 9a of the source region 8 and the drain region 8, 9 of the p⁺-type, for example. Thereafter, annealing is carried out for electrical activation of impurities introduced by ion implantation. As a result, a p-channel MIS transistor having an LDb (lightly doped drain) structure is obtained.

In the next process, a cobalt (Co) film (not shown), for example, is deposited as the metal film on the entire substrate surface by any existing method such as sputtering to form the metal silicide layer, and it is subsequently annealed to bring about interaction of the cobalt film with the silicon substrate 1 and the gate electrode 5 composed of the p-type polycrystalline silicon layer directly contacting the cobalt film and thereby change the cobalt to a suicide. In this manner, as shown in FIG. 8, a cobalt silicide (CoSi₂) layer 10 is formed on the source regions 8, 9 and the gate electrode 5. The remainder part of the cobalt film having failed to participate the interaction is removed thereafter.

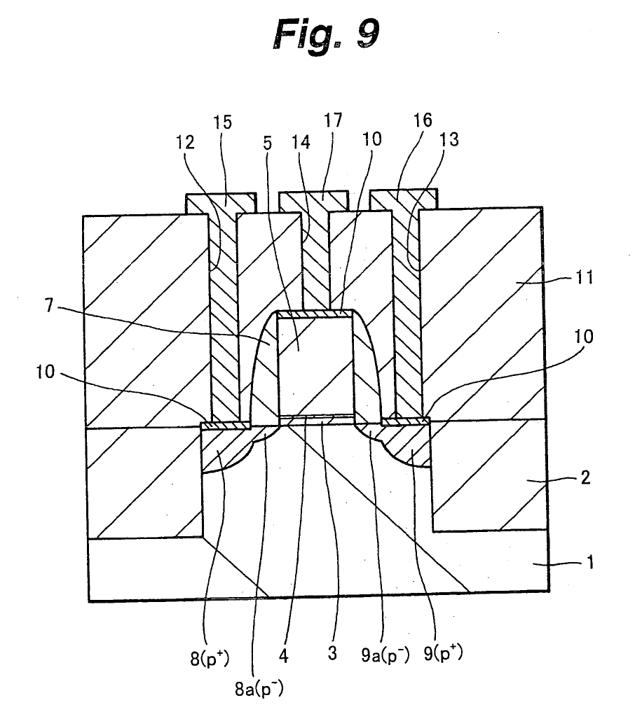

Next as shown in. FIG. 9, an inter-layer insulating film 11 made of silicon oxide film, phosphorus silicate glass (PSG) film, boron phosphorus silicate glass (BPSG) film, silicon nitride film or multi-layered film of those films, for example, is formed on the entire substrate surface by any existing method such as normal-pressure CVD or low-pressure CVD, for example, and selective portions of the inter-layer insulating film 11 above the source region 8, drain region 9 and gate electrode 5 are removed by etching to form contact holes 12, 13, 14.

In the next process, a wiring material film such as aluminum (Al) film, Al alloy film, or other metal film is formed on the entire substrate surface via a barrier metal film by any known method such as vacuum evaporation or sputtering, for example. This film is thereafter selectively etched by RIE, for example, to make out a predetermined pattern of wirings 15, 16, 17 connecting the source region 8, drain region 9 and gate electrode 5 via the contact holes 12, 13, 14, respectively.

After that, through other steps such as a step of forming an upper-layered wiring, if necessary, the intended complementary MIS semiconductor device is completed.

As explained above according to the foregoing embodiment, since the very thin nitride layer 4 of a close-packed structure is formed by nitriding of the top surface of the high-dielectric-constant film by using radical nitrogen, and the B-contained p-type polycrystalline silicon layer is formed as the gate electrode 5 on the nitride layer 4, even if B diffuses externally from the p-type polycrystalline silicon layer forming the gate electrode 5 due to various kinds of annealing carried out in the manufacturing process after deposition of the gate electrode 5, the nitride layer 4 prohibits such diffusion and prevents B from penetrating the dielectric film 3 and diffusing into the silicon substrate 1 through the high-dielectric-constant film 3. Therefore, it is possible to prevent fluctuation of the threshold voltage of the p-channel MIS transistor, which will occur if B diffuses into the silicon substrate, and to significantly reduce characteristic defects of the complementary MIS transistor and thereby improve the production yield of the complementary MIS semiconductor devices. Additionally, since the nitride film 4 is as thin as 0.2-0.3 nm, the semiconductor device can make the best use of the high dielectric constant of the high-dielectric-constant film 3. Furthermore, since the high-dielectric-constant film 3 generally exhibits high resistance to dielectric breakdown voltage and long-term reliability, a highly reliable p-channel MIS transistor can be obtained.

Having described a specific preferred embodiment of the present invention with reference to the accompanying drawings, it is to be understood that the invention is not limited to that precise embodiment, and that various changes and modifications may be effected therein by one skilled in the art without departing from the scope or the spirit of the invention as defined in the appended claims.

For example, numerical values, materials, structures, shapes, processes, etc. specifically shown in conjunction with the first embodiment are nothing more than examples, and other numerical values, materials, structures, shapes, processes, etc. may be used if appropriate.

More specifically, although the foregoing embodiment has been explained as forming the non-doped polycrystalline silicon film on the entire substrate surface and introducing ions of the p-type impurity into it for the purpose of forming the p-type polycrystalline silicon layer as the gate electrode 5, it may be modified to dope the p-type impurity upon forming the polycrystalline silicon layer by CVD. Furthermore, it may be modified to pattern the non-doped polycrystalline silicon layer to the shape of the gate electrode and thereafter dope the polycrystalline film with the p-type impurity.

Further, the foregoing embodiment uses a radical nitriding apparatus shown in FIG. 10 for nitriding of the top surface of the high-dielectric-constant film 3. However, the radical nitriding apparatus is nothing more than an example, and an apparatus having a different configuration may be used. Additionally, although the radical nitriding apparatus shown in FIG. 10 is of a sheet-fed type, a batch-type radical nitriding apparatus may be used if necessary.

As described above, according to the invention, since the nitride layer is formed on the high-dielectric-constant film, the p-type impurity is effectively prohibited from diffusing from the p-type impurity-contained layer such as a p-type polycrystalline silicon layer used as the gate electrode into the semiconductor substrate after penetrating the enhanced dielectric layer during or after annealing carried out in the manufacturing process of the semiconductor device. Therefore, it is possible to prevent fluctuation of the threshold voltage of the p-channel MIS transistor, which will occur if the p-type impurity diffuses into the silicon substrate.

What is claimed is:

1. A semiconductor device comprising:
a semiconductor substrate;
a high-dielectric-constant film on the semiconductor substrate; and
a nitride layer on the high-dielectric-constant film.

2. The semiconductor device according to claim 1 further comprising a p-type impurity-contained layer on the nitride layer.

3. The semiconductor device according to claim 1 wherein the nitride layer is formed by introducing nitrogen into a top surface portion of the high-dielectric-constant film.

4. The semiconductor device according to claim 1 wherein the semiconductor substrate is a silicon substrate or a silicon layer.

5. The semiconductor device according to claim 2 wherein the p-type impurity-contained layer is a boron-contained silicon layer.

6. A method of manufacturing a semiconductor device comprising the steps of:
forming a high-dielectric-constant film on a semiconductor substrate; and
forming a nitride layer over the top surface of the high-dielectric-constant film.

7. The method according to claim 6 further comprising the step of forming a p-type impurity-contained layer on the nitride layer.

8. The method according to claim 6 wherein the nitride layer is formed by introducing nitrogen into a top surface portion of the high-dielectric-constant film.

9. The method according to claim 6 wherein the nitride layer is formed by introducing nitrogen into the top surface portion of the high-dielectric-constant film by plasma nitriding.

10. The method according to claim 6 wherein the nitride layer is formed by introducing nitrogen into the surface portion of the high-dielectric-constant film by using radical nitrogen.

11. The method according to claim 6 wherein the semiconductor substrate is a silicon substrate or a silicon layer.

12. The method according to claim 7 wherein the p-type impurity-contained layer is a boron-contained silicon layer.

13. A semiconductor device comprising:
A semiconductor substrate;
a gate insulating film on the semiconductor substrate; and
a gate electrode formed on the gate insulating film and including at least a p-type impurity-contained layer,
wherein the gate insulating film includes a high-dielectric-constant film and a nitride layer on the high-dielectric-constant film.

14. The semiconductor device according to claim 13 wherein the nitride layer is formed by introducing nitrogen into a top surface portion of the high-dielectric-constant film.

15. The semiconductor device according to claim 13 wherein the semiconductor substrate is a silicon substrate or a silicon layer.

16. The semiconductor device according to

13 wherein the p-type impurity-contained layer is a boron-contained silicon layer.

17. A method of manufacturing a semiconductor device comprising the steps of:
forming a gate insulating film on a semiconductor substrate; and
forming a gate electrode including at least a p-type impurity-contained layer on the gate insulating film,
wherein the step of forming the gate insulating film includes a step of forming a high-dielectric-constant film on the semiconductor substrate, and a step of forming a nitride layer on the top surface of the high-dielectric-constant film.

18. The method according to claim 17 wherein the nitride layer is formed by introducing nitrogen into a top surface portion of the high-dielectric-constant film.

19. The method according to claim 17 wherein the nitride layer is formed by introducing nitrogen into the top surface portion of the high-dielectric-constant film by plasma nitriding.

20. The method according to claim 17 wherein the nitride layer is formed by introducing nitrogen into the surface portion of the high-dielectric-constant film by using radical nitrogen.

21. The method according to claim 17 wherein the semiconductor substrate is a silicon substrate or a silicon layer.

22. The method according to claim 17 wherein the p-type impurity-contained layer is a boron-contained silicon layer.
